(19) United States
(12) Patent Application Publication
(10) Pub. No.: US 2008/0121877 A1
(43) Pub. Date: May 29, 2008

(54) THIN FILM TRANSISTOR WITH ENHANCED STABILITY

(75) Inventors: David A. Ender, New Richmond, WI (US); Michael W. Bench, Eagan, MN (US); Steven D. Theiss, Woodbury, MN (US); Jonathan A. Nichols, New Market, MN (US)

Correspondence Address: 3M INNOVATIVE PROPERTIES COMPANY, PO BOX 33427, ST. PAUL, MN, 55133-3427, US

(73) Assignee: 3M Innovative Properties Company

(21) Appl. No.: 11/563,469

(22) Filed: Nov. 27, 2006

(51) Int. Cl. H01L 29/22

(52) U.S. Cl. 257/43; 257/E29.094

(57) ABSTRACT

Electronic devices such as transistors are disclosed. The electronic device includes an electrically conductive gate electrode, an anodized layer disposed on the gate electrode, a dielectric layer disposed on the anodized layer, and a semiconductor oxide layer that has a channel region. The channel region is disposed on the dielectric layer and has an internal resistance. The internal resistance of the channel can change when an electrical signal is applied to the gate electrode.

### FIELD OF THE INVENTION

This invention generally relates to electronic devices. The invention is particularly applicable to transistors including thin film transistors.

### BACKGROUND

Transistors are currently used in a wide variety of applications such as signal modulation, signal regulation and amplification, memory circuits, and signal switching. Two common types of transistors are bipolar junction transistors (BJT) and field-effect transistors (FET). A BJT typically has three terminals labeled emitter, collector, and base. An FET transistor typically has three main terminals commonly referred to as gate, drain, and source. Many FETs have a fourth terminal commonly referred to as the body.

### SUMMARY OF THE INVENTION

Generally, the present invention relates to electronic systems. In one embodiment, an electronic device includes an electrically conductive gate electrode, an anodized layer disposed on the gate electrode, a dielectric layer disposed on the anodized layer, and a semiconductor oxide layer that has a channel region. The channel region is disposed on the dielectric layer and has an internal resistance. The internal resistance of the channel can change when an electrical signal is applied to the gate electrode.

### BRIEF DESCRIPTION OF DRAWINGS

The invention may be more completely understood and appreciated in consideration of the following detailed description of various embodiments of the invention in connection with the accompanying drawings, in which:

FIG. 1 is a schematic side-view of an electronic device;

FIG. 2 is a schematic side-view of another electronic device;

FIGS. 3A-3B are schematic representations of devices at intermediate stages or steps in a process for fabricating an electronic device;

FIG. 4 is a schematic side-view of an electronic device; and

FIG. 5 is a plot of normalized drain current as a function of operation time for two transistors.

The same reference numeral used in multiple figures refers to the same or similar elements having the same or similar properties and functionalities.

### DETAILED DESCRIPTION

This application teaches new electronic devices including new transistors capable of exhibiting enhanced performance stability.

Specifically, transistors are disclosed in which an electrically conductive electrode is insulated from the remainder of the transistor. The electrode is covered with two dielectric layers. A first layer is an anodized layer that substantially conforms to the surface of the electrode. The first layer allows for low cost, high-yield, and efficient manufacture because the anodization process is substantially insensitive to factors such as the surface profile and surface cleanliness of the electrode. A second dielectric layer disposed on the first layer provides enhanced performance stability that may not be achievable by the first layer alone. In the case of some transistors, the two dielectric layers isolate a gate electrode from a semiconductor region.

These transistors can be manufactured with high device yields and can exhibit improved device performance and operational lifetime.

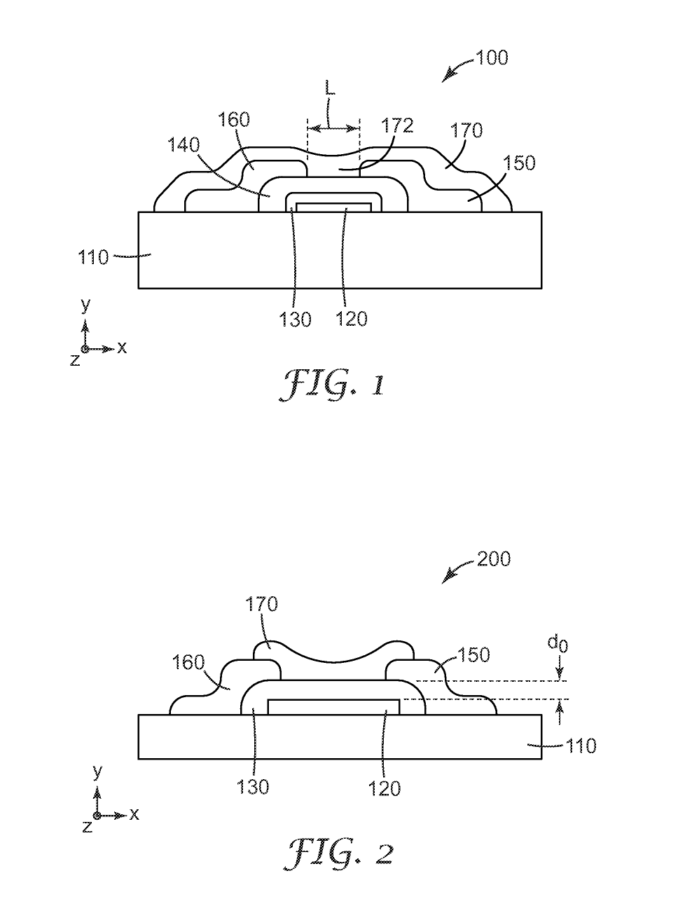

FIG. 1 is a schematic view of a cross-section of an electronic device 100. Electronic device 100 includes a gate electrode 120 that is disposed on an electrically insulating substrate 110. Electronic device 100 further includes an anodized layer 130 disposed on gate electrode 120. Anodized layer 130 is formed by anodizing an electrically conductive material that is capable of being anodized. In some cases, anodized layer 130 is a dielectric. In some other cases, anodized layer 130 may be partially electrically conductive. In some cases, anodized layer 130 is a single layer. In some other cases, anodized layer 130 is a multilayer where one or more layers can be anodized layers.

In some cases, anodized layer 130 is formed by partially anodizing gate electrode 120. For example, layers 120 and 130 may be formed by first depositing and patterning a metal on the substrate. The patterned metal can then be partially anodized to form the anodized layer 130, which, in some cases, can be electrically insulating. The non-anodized portion of the deposited metal forms gate electrode 120.

In some cases, anodized layer 130 may be formed by fully or partially anodizing a layer that is different than gate electrode 120. In such cases, anodized layer 130 can be formed by, for example, first depositing on gate electrode 120 a material that is capable of being anodized. Next, the deposited material can be fully or partially anodized to form anodized layer 130.

Electronic device 100 also includes a dielectric layer 140 disposed on top of anodized layer 130. Electronic device 100 further includes electrically conductive patterned source electrode 160 and drain electrode 150 disposed on top of dielectric layer 140 and substrate 110. Electronic device 100 further includes a semiconductor layer 170 that is disposed on electrodes 150 and 160 and on dielectric layer 140 between electrodes 150 and 160.

In some cases, electronic device 100 is symmetrical, meaning that source electrode 160 and drain electrode 150 can be interchanged with little or no change in the performance and characteristics of the electronic device. In some other cases, electronic device 100 may be asymmetrical, meaning that interchanging the source and drain electrodes will result in a substantial change in the device characteristics.

As used herein, I_{D}, I_{S}, and I_{G} refer to electrical currents flowing through drain 150, source 160, and gate 120, respectively. Similarly, V_{D}, V_{S}, and V_{G} refer to voltages at drain 150, source 160, and gate 120, respectively.

The portion of semiconductor 170 positioned between electrodes 150 and 160 defines a channel region 172. In some cases, the channel length L, which is the separation between source electrode 160 and drain electrode 150, is in a range from about 0.5 microns to about 200 microns, or from about 0.5 microns to about 100 microns, or from about 0.5 microns to about 30 microns, or from about 1 micron to about 15 microns, or from about 1 micron to about 10 microns.

A voltage V_{DS}=V_{D}−V_{S} applied between drain electrode 150 and source electrode 160 can result in currents I_{D} and I_{S} flowing through drain and source electrodes 150 and 160, respectively. In some cases, such as for an n-channel enhancement MOSFET, the electrical resistance of channel 172 may be reduced by applying a voltage V_{GS}=V_{G}−V_{S} between gate electrode 120 and source electrode 150, greater than a threshold value Vₜ. The channel resistance is reduced because the applied above-threshold V_{GS} can, for example, result in an accumulation of mobile electrons in the channel region.

In other cases, where V_{GS} is less than Vₜ (cut-off region), the electrical resistance of channel 172 can remain large and substantially insensitive to V_{GS}. In some such cases, the electrical resistance of channel 172 between electrodes 150 and 160 is greater than about 10⁸ ohms, or greater than about 10¹⁰ ohms, or greater than about 10¹² ohms.

For V_{GS} greater than Vₜ, the channel resistance can change substantially linearly as a function of the applied V_{GS}, for example, where V_{DS}≦V_{GS}−Vₜ. In such cases, I_{D} can be a linear function of both V_{GS} and V_{DS}.

For ease of description and without loss of generality, it is assumed that electronic device 100 is in a cut-off region or an “off” state for V_{GS} less than Vₜ. It will, however, be appreciated by those skilled in the art that in some cases, such as where device 100 is a p-channel enhancement MOSFET, the device will be in an “off” state for V_{GS} greater than Vₜ. In such cases, for V_{GS} less than Vₜ and V_{DS}≧V_{GS}−Vₜ, the channel resistance can change substantially linearly as a function of V_{GS}.

In some applications, dielectric layer 140 and a dielectric anodized layer 130 electrically insulate gate electrode 120 from the rest of electronic device 100 such as electrodes 150 and 160 and semiconductor layer 170 including channel 172. The insulation can result in very small currents I_{G} flowing through the gate electrode. In some cases, I_{G} is less than about 10⁻¹⁰ amps, or less than about 10⁻¹¹ amps, or less than about 10⁻¹² amps.

In cases where I_{G} is very small, drain current I_{D} and source current I_{S} are substantially equal when the transistor is in the “on” state. In some cases, the magnitude of the difference between I_{D} and I_{S} is less than about 10⁻³ amps, or less than about 10⁻⁴ amps, or less than about 10⁻⁵ amps.

In some cases, gate electrode 120 can be a metal and anodized layer 130 can be formed by anodizing an outer portion of the metal including the outer surface of the metal. For example, gate electrode can be an aluminum gate electrode and anodized layer 130 can be anodized aluminum. For example, an aluminum layer may be first deposited on substrate 110 and patterned using, for example, conventional photolithography. The patterned aluminum layer can then be partially anodized to form anodized aluminum layer 130. The anodization process can be, for example, similar to those disclosed in, for example, U.S. Pat. No. 6,267,861 (Kinard et al.). In some cases, gate electrode 120 can be the non-anodized portion of the patterned aluminum layer. During the anodization process some portions of the patterned aluminum layer may be protected from being anodized for subsequent connection to, for example, a controller circuitry.

In a typical anodization process, a metal layer to be anodized is biased at a voltage and immersed in an anodization solution that can include, for example, tartaric acid and ethylene glycol. In some cases, the anodization process can require the immersion to last for minutes, for example, five minutes during which the anodization solution can be circulated or agitated. During the immersion, the anodization solution tends to reach and wet the surface of the metal layer even in areas where the metal layer may be covered by, for example, a small particle. Such penetration by the anodization solution can result in substantially uniform anodization of the metal layer even in areas where the metal is covered by a small foreign object such as a small dirt particle.

Consequently, a subsequent removal of the particle does not result in a pinhole in the anodized layer which would expose the metal layer. As a result, an advantage of using an anodization process to form anodized layer 130 is that the anodization substantially conforms to the surface profile of the layer being anodized even if in some locations the surface is covered with, for example, small particles. In contrast, if anodized layer 130 is replaced with a dielectric layer that is formed by, for example, vapor depositing a dielectric material onto the gate electrode, an area of the gate electrode covered by a particle may not be coated during the deposition process, resulting in the gate electrode being exposed in the area after the particle is removed, for example, during further processing.

Another advantage of using an anodization process to form anodized layer 130 is that anodization can result in a substantially uniform insulation of the gate electrode. For example, during the anodization process more electrical current tends to flow through an area that is not as anodized, and therefore not as insulating, as the neighboring regions. The additional current intensifies the anodization of the area until the entire anodized region becomes uniformly insulating.

In some cases, gate electrode 120 can be any material that is capable of being at least partially anodized to form anodized layer 130. In general, gate electrode 120 can be any anodizable metal. For example, gate electrode 120 can be aluminum, tantalum, niobium, titanium, zirconium, beryllium, magnesium, yttrium, zinc, copper, tin, bismuth, silicon, and hafnium. As another example, gate electrode 120 can be an alloy of any anodizable metal or a combination of anodizable metals.

Source electrode 160 and drain electrode 150 may be any metal that may be desirable in an application. Exemplary metals that may be used to fabricate the drain and source electrodes include aluminum, gold, copper, and silver.

In some cases, the source and drain electrodes can be formed by first depositing an electrically conductive layer, such as a metal, on anodized layer 130 and substrate 110. The deposited conductive layer can then be patterned, for example, by using an etchant in a conventional photolithography process. In some cases, during the patterning process the etchant may attack and etch anodized layer 130. For example, the gate electrode 120 may be made of aluminum, anodized layer 130 may be anodized aluminum, and the deposited conductive layer may be aluminum. The deposited conductive layer may be patterned using an aluminum etchant such as a solution that includes phosphoric acid, acetic acid, nitric acid, and water described in, for example, U.S. Pat. No. 4,589,961 (Gershenson). In such a case, the etching solution is also capable of etching anodized layer 130, which may not be desirable.

In some cases, to prevent the etching of anodized layer 130 during patterning of the source and drain electrodes, anodized layer 130 may be protected by covering the anodized layer with a dielectric layer 140 that does not etch or etches very little by an etchant used to form the source and drain electrodes. For example, the dielectric layer can be made of silicon dioxide (SiO₂) that does not tend to react with etchants suitable for etching, for example, aluminum.

In some cases, the presence of dielectric layer 140 has the added advantage of improving device stability. In particular, dielectric layer 140 can stabilize the drain current I_{D} with time during operation of device 100.

Electronic device 100 can, for example, be a transistor, such as a metal oxide semiconductor field effect transistor (MOSFET) or an insulated gate bipolar transistor (IGBT). In general, electronic device 100 can be any device where it may be desirable to have a stack of two dielectric layers where one layer is an anodized layer and the other layer improves operational stability.

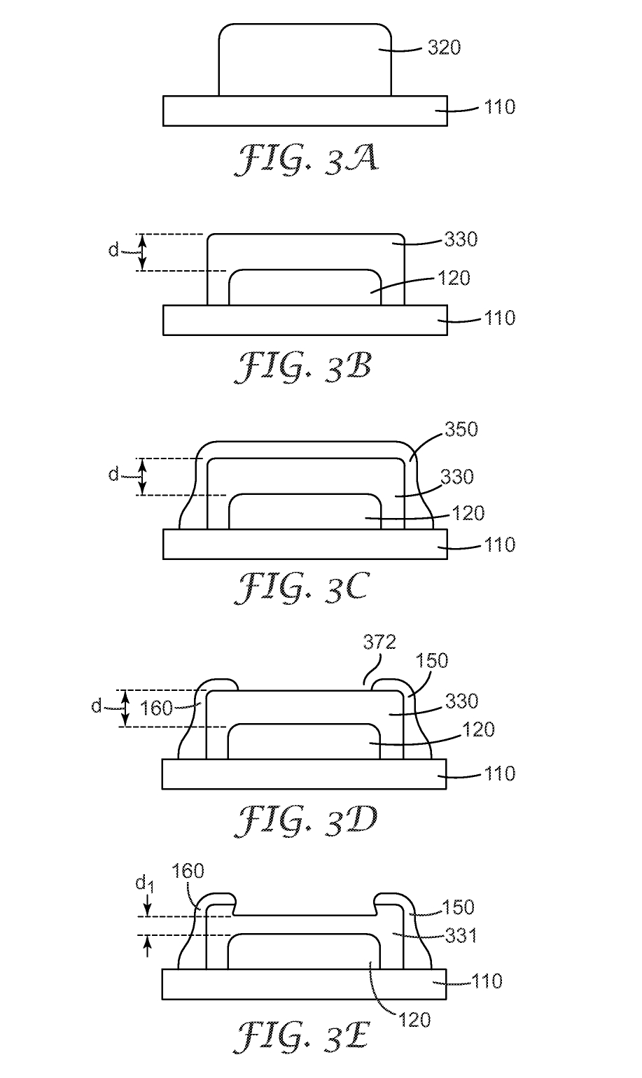

In some applications, electronic device 100 may not include dielectric layer 140 such as electronic device 200 shown schematically in FIG. 2. In electronic device 200, anodized layer 130 has a desired thickness dₒ. Electronic device 200 can be fabricated using a process schematically described in FIGS. 3A-3E.

First, a patterned electrically conductive layer 320 is formed by depositing and patterning an electrically conductive layer, such as a metal layer, on substrate 110. Layer 320 may be deposited using any suitable known method such as thermal evaporation, e-beam evaporation, sputtering, flame hydrolysis, casting, plasma deposition, or any other deposition method that may be desirable in an application. In some cases, conductive layer 320 can be the gate electrode. In some other cases, a portion of conductive layer 320 can become the gate electrode.

Next, an anodized layer 330 is formed on conductive layer 320. Anodized layer 330 has an average thickness d, where d is greater than a desired final thickness dₒ. In some cases, patterned electrically conductive layer 320 is anodizable, and anodized layer 330 is formed by anodizing patterned electrically conductive layer 320 until the anodized portion of electrically conductive layer 320 has a thickness d that is greater than the desired thickness dₒ. In such cases, the non-anodized portion of electrically conductive layer 320 forms gate electrode 120 as shown schematically in FIG. 3B.

In some other cases, patterned electrically conductive layer 320 may be covered with an anodizable metal layer that is partially or fully anodized to form anodized layer 330. In such cases, patterned electrically conductive layer 320 can be the gate electrode similar to gate electrode 120.

Next, an electrically conductive layer 350 is deposited on anodized layer 330 as shown schematically in FIG. 3C. In some cases, electrically conductive layers 320 and 350 are made of the same electrically conductive material, such as aluminum. In general, electrically conductive layers 320 and 350 may or may not be made of the same electrically conductive material.

The next step includes using a first etchant in an etching process to pattern electrically conductive layer 350 to form drain and source electrodes 150 and 160, respectively. The etching process also exposes anodized layer 330 in area 372 as shown schematically in FIG. 3D. The etching process can be any known etching process that may be suitable in an application. Known etching processes include wet or dry chemical etching, and reactive ion etching. The first etchant can be any etchant that is capable of etching conductive layer 350. In some cases, electrically conductive layer is an aluminum layer and the first etchant is an etching solution that etches the aluminum layer using a spray process.

Next, a second etchant is used to etch anodized layer 330 in exposed area 372 until thickness d of the anodized layer is reduced to d₁ which is substantially equal to the desired thickness dₒ as shown schematically in FIG. 3E, thus forming anodized layer 331.

Next, a semiconductor layer similar to semiconductor layer 170 and/or a dielectric layer similar to dielectric layer 140 may be disposed on electrodes 150 and 160 and anodized layer 331.

In some cases, some or all the steps described in connection with FIGS. 3A-3E may be carried out sequentially. In general, however, the described steps need not be carried out sequentially. Furthermore, there may be additional steps included in the described fabrication process, such as rinsing steps, baking steps, and/or photolithographic steps such as coating and exposing a photoresist.

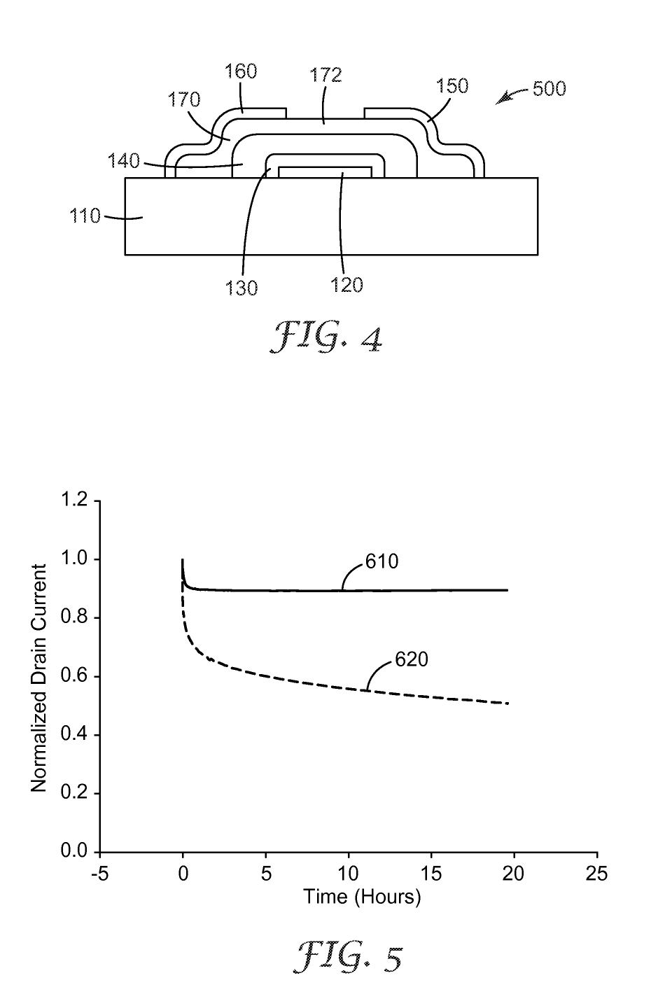

FIG. 4 is a schematic view of a cross-section of an electronic device 500. In electronic device 500, semiconductor layer 170 is disposed between dielectric layer 140 and the source and drain electrodes 160 and 150, respectively. In some cases, since semiconductor layer 170 covers anodized layer 130, dielectric layer 140 may not be needed to prevent the etching of anodized layer 130 during patterning of electrodes 150 and 160. In such cases, electronic device 500 may still include layer 140 in order to improve the performance of device 500 by, for example, stabilizing current I_{D} as a function of time at a desired operating point.

Some advantages associated with the disclosed devices are illustrated by the following example. The particular materials, amounts and dimensions recited in this example, as well as other conditions and details, should not be construed to unduly limit the present invention. A test device similar to the device of FIG. 4 was fabricated. First, 200 angstroms of SiO₂ tie-layer was sputter coated onto a glass substrate for improving adhesion between the glass substrate and subsequent layers. Next, 1500 angstroms of aluminum was sputtered onto the tie-layer and patterned. Next, the aluminum layer was partially anodized resulting in a 975 angstroms thick anodized aluminum layer which was essentially aluminum oxide (Al₂O₃). The remaining 525 angstroms of the sputtered aluminum layer formed the gate electrode.

To form the dielectric layer, 200 angstroms of SiO₂ was e-beam vapor deposited onto the anodized aluminum layer. Next, 550 angstroms of ZnO was sputtered onto the SiO₂ dielectric layer to form the semiconductor layer. Next, the source and drain electrodes were formed by sputter coating and patterning 1000 angstroms of aluminum onto the ZnO layer. The channel length (distance between the source and drain electrodes) was 50 microns. The channel width was 500 microns.

A control device was also fabricated using the same process and device parameters except that the control device did not have an SiO₂ dielectric layer. Both the test device and the control device were activated by applying a 2 volt DC signal to the drain electrodes. The source electrodes were grounded. A 250 Hertz square-wave voltage signal with a 1:100 or 1% duty cycle (the period of the square-wave was 100 times each pulse-width) was applied to each gate electrode. The square-wave had a maximum value of 20 volts corresponding to the “on” state of the device and a minimum value of −5 volts corresponding to the “off” state of the device.

For each device the drain current I_{D} was tracked during the “on” state. The results are shown in FIG. 5, where the vertical axis is normalized on-current and the horizontal axis is time. Curve 610 shows the drain current I_{D} of the test device and curve 620 shows the drain current I_{D} of the control device. FIG. 5 clearly shows that the presence of the SiO₂ dielectric layer in the test device substantially improved the stability of drain current I_{D}.

Curve 620 indicates that the threshold voltage Vₜ for the control device gradually increased with operation time. In contrast, curve 610 indicates that the threshold voltage of the test device remained essentially unchanged with operation time after an initial stabilization period.

As used herein, terms such as “vertical”, “horizontal”, “above”, “below”, “left” “right”, “upper” and “lower”, “top” and “bottom” and other similar terms, refer to relative positions as shown in the figures. In general, a physical embodiment can have a different orientation, and in that case, the terms are intended to refer to relative positions modified to the actual orientation of the device. For example, even if the construction in FIG. 1 is inverted as compared to the orientation in the figure, gate electrode 120 is still considered to be on “top” of substrate 110.

All patents, patent applications, and other publications cited above are incorporated by reference into this document as if reproduced in full. While specific examples of the invention are described in detail above to facilitate explanation of various aspects of the invention, it should be understood that the intention is not to limit the invention to the specifics of the examples. Rather, the intention is to cover all modifications, embodiments, and alternatives falling within the spirit and scope of the invention as defined by the appended claims.

What is claimed is:

1. An electronic device, comprising:
an electrically conductive gate electrode;
an anodized layer disposed on the gate electrode;
a dielectric layer disposed on the anodized layer; and
a semiconductor oxide layer having a channel region, the channel region being disposed on the dielectric layer and having an internal resistance, such that the internal resistance can change when an electrical signal is applied to the gate electrode.

2. The electronic device of claim 1, wherein the device is or comprises an insulated gate bipolar transistor.

3. The electronic device of claim 1, wherein the device is or comprises a metal oxide semiconductor field effect transistor.

4. The electronic device of claim 1, wherein the gate electrode comprises a metal and the anodized layer comprises the metal anodized.

5. The electronic device of claim 1, wherein the gate electrode comprises aluminum.

6. The electronic device of claim 1, wherein the anodized layer comprises anodized aluminum.

7. The electronic device of claim 1 further comprising electrically conductive source and drain electrodes, the channel region being disposed between the source and drain electrodes.

8. The electronic device of claim 7, wherein the source electrode is disposed between the semiconductor oxide layer and the dielectric layer.

9. The electronic device of claim 7, wherein the semiconductor oxide layer is disposed between the dielectric layer and the source electrode.

10. The electronic device of claim 1, wherein the semiconductor oxide layer comprises ZnO.

11. The electronic device of claim 1, wherein the dielectric layer comprises SiO₂.

12. The electronic device of claim 1, wherein the dielectric layer is disposed on the anodized layer by e-beam evaporation.

13. The electronic device of claim 1, wherein the dielectric layer is disposed on the anodized layer by sputtering.
